(19) United States
(12) Patent Application Publication
(10) Pub. No.: US 2015/0021626 A1
(43) Pub. Date: Jan. 22, 2015

(54) LIGHT-EMITTING DEVICE

(71) Applicant: PANASONIC CORPORATION, Osaka (JP)

(72) Inventors: Akiko Nakamura, Kagoshima (JP); Yuji Takase, Shiga (JP); Masahiro Kume, Kagoshima (JP); Masanori Hiroki, Kagoshima (JP)

(73) Assignee: PANASONIC CORPORATION, Osaka (JP)

(21) Appl. No.: 14/380,046

(22) PCT Filed: Apr. 11, 2013
(86) PCT No.: PCT/JP2013/002484

§ 371 Date: Aug. 20, 2014

(30) Foreign Application Priority Data
Apr. 27, 2012 (JP) 2012-102224

(51) Int. Cl. H01L 33/38

(52) U.S. Cl. CPC H01L 33/38
USPC 257/79

(57) ABSTRACT

A light-emitting device includes: a layered semiconductor body including an n-type layer, a light-emitting layer, and a p-type layer stacked in sequence; an n-side electrode formed on part of the n-type layer exposed in a via formed in the layered semiconductor body to be non-conductive with the light-emitting layer and the p-type layer; and a p-side electrode formed on the p-type layer. The n-side electrode has an annular shape on a principal surface of the n-type layer.

### TECHNICAL FIELD

The present disclosure relates to light-emitting devices, particularly to a light-emitting device including an n-side electrode conductively connected to an n-type layer through a via penetrating the n-type layer.

### BACKGROUND ART

In a light-emitting device including an n-type semiconductor layer, a light-emitting layer, and a p-type semiconductor layer stacked in sequence, sufficient current diffusion throughout the light-emitting layer is desirable. The current diffusion is particularly important in a light-emitting device having a large light-emitting area. For example, Patent Document 1 describes a contact mode for large-area and small-area light-emitting semiconductor flip-chip devices in which a plurality of n-type square-shaped vias arranged in a dot array pattern are formed by etching to penetrate an active region (a light-emitting layer) and a p-type semiconductor layer, and n-contacts (n-side electrodes) are deposited in the inside of the vias to contact an n-type semiconductor layer.

### CITATION LIST

### Patent Document

[Patent Document 1] Japanese Unexamined Patent Publication No. 2004-47988

### SUMMARY OF THE INVENTION

### Technical Problem

In the flip-chip semiconductor light-emitting device described in Patent Document 1, the n-contacts are arranged in the dot array pattern, and the diffusion can be expected to a certain degree. Thus, a relatively large area of the active region (the light-emitting layer) and the p-type layer can be ensured, and brightness can be improved. However, each of the n-contacts is relatively small in diameter, and the diffusion is limited. When an area of the n-contacts is small, a resistance in a forward direction is increased to raise an operating voltage. Conversely, when the diameter of each of the n-type vias is increased to increase the area of the n-contacts, an area of the p-type layer and the light-emitting layer is reduced, and a light-emitting region is reduced. This may reduce the brightness.

In view of the foregoing, the present disclosure has been achieved to provide a light-emitting device with high brightness by ensuring the area of the light-emitting region and favorable diffusion of an injected current.

### Solution to the Problem

An aspect of the present disclosure is directed to a light-emitting device including: a layered semiconductor body including an n-type layer, a light-emitting layer, and a p-type layer stacked in sequence; an n-side electrode formed on part of the n-type layer exposed in a via formed in the layered semiconductor body to be non-conductive with the light-emitting layer and the p-type layer; and a p-side electrode formed on the p-type layer. The n-side electrode has an annular shape on a principal surface of the n-type layer.

According to the light-emitting device of the aspect, the current can be diffused not only in an outward direction, but also in an inward direction of the annular n-side electrode. Thus, the current can be spread over a wide area of the n-type layer, and the light-emitting layer can efficiently and uniformly emit light.

### Advantages of the Invention

The present disclosure can ensure the light-emitting region, can ensure favorable diffusion of the injected current, and can improve the brightness of the light emitted by the light-emitting device.

### BRIEF DESCRIPTION OF THE DRAWINGS

FIG. 1(a) and FIG. 1(b) illustrate a light-emitting device of an embodiment. FIG. 1(a) is a cross-sectional view taken along the line 1a-1a in FIG. 1(b), and FIG. 1(b) is a plan view.

FIG. 2(a)-FIG. 2(e) are cross-sectional views illustrating steps of a method of manufacturing the light-emitting device of the embodiment.

FIG. 3(a)-FIG. 3(d) are cross-sectional views illustrating steps of the method of manufacturing the light-emitting device of the embodiment.

FIG. 4(a)-FIG. 4(d) are cross-sectional views illustrating steps of the method of manufacturing the light-emitting device of the embodiment.

FIG. 5(a)-FIG. 5(e) are cross-sectional views illustrating steps of the method of manufacturing the light-emitting device of the embodiment.

FIG. 6 is a cross-sectional view illustrating the light-emitting device of the embodiment mounted on a sub-mount device.

FIG. 7 is a graph illustrating a relationship between a percentage of an area of an n-side electrode and a forward voltage in the light-emitting device of the embodiment and a light-emitting device of a conventional example.

FIG. 8(a) and FIG. 8(b) illustrate an effect of a planar shape of the n-side electrode. FIG. 8(a) is a schematic plan view illustrating the n-side electrode of the conventional light-emitting device, and FIG. 8(b) is a schematic plan view illustrating the n-side electrode of the light-emitting device of the embodiment.

FIG. 9(a)-FIG. 9(d) are schematic plan views illustrating first to fourth alternative examples of the n-side electrode of the light-emitting device of the embodiment.

FIG. 10(a)-FIG. 10(d) are schematic plan views illustrating fifth to eighth alternative examples of the n-side electrode of the light-emitting device of the embodiment.

FIG. 11(a) and FIG. 11(b) illustrate a seventh alternative example of the light-emitting device of the embodiment. FIG. 11(a) is a cross-sectional view taken along the line XIa-XIa in FIG. 11(b), and FIG. 11(b) is a plan view.

FIG. 12 is a cross-sectional view illustrating the seventh alternative example of the light-emitting device of the embodiment mounted on a sub-mount device.

### DESCRIPTION OF EMBODIMENTS

A light-emitting device of an embodiment includes: a layered semiconductor body including an n-type layer, a light-emitting layer, and a p-type layer stacked in sequence; an n-side electrode formed on part of the n-type layer exposed in a via formed in the layered semiconductor body to be non-conductive with the light-emitting layer and the p-type layer; and a p-side electrode formed on the p-type layer. The n-side electrode has an annular shape on a principal surface of the n-type layer.

For example, when the n-side electrode is formed as dots, the current is diffused merely in an outward direction of the n-side electrode even when the number of the dots is increased. In the light-emitting device of the embodiment, the n-side electrode has an annular shape, and the current can be diffused not only in the outward direction, but also in an inward direction of the n-side electrode. Thus, the current can be spread over a wide area of the n-type layer, and the light-emitting layer can efficiently and uniformly emit light.

The light-emitting device of the embodiment may further include: an n-side pad electrode which is formed above the p-type layer of the layered semiconductor body, is electrically connected to the n-side electrode, and is provided in an n-side connection region connected to an n-side power supply; a p-side pad electrode which is formed above the p-type layer of the layered semiconductor body, is electrically connected to the p-side electrode, and is provided in a p-side connection region connected to a p-side power supply; a p-side insulating layer formed between the n-side pad electrode and part of the p-side electrode included in the n-side connection region; and an n-side insulating layer formed between the p-side pad electrode and part of the n-side electrode included in the p-side connection region.

In this configuration, planar shapes of the n-side pad electrode and the p-side pad electrode connected to the external n-side power supply and the external p-side power supply can optionally be designed.

In the light-emitting device of the embodiment, the n-side electrode may have a closed annular shape.

In this configuration, the current can uniformly be diffused in outward and inward directions of the n-side electrode.

In the light-emitting device of the embodiment, the n-side electrode may have a partially opened annular shape.

In this configuration, regions inside and outside the via can be brought into conduction, and the planar shapes of the n-side electrode and the p-side electrode can be designed with increased flexibility.

In the light-emitting device of the embodiment, the n-side electrode may be circular or polygonal.

In the light-emitting device of the embodiment, the layered semiconductor body may have a corner when viewed in plan, and the n-side electrode may have an angled part facing the corner of the layered semiconductor body.

In this configuration, the current can be diffused from the angled part of the n-side electrode to the corner of the layered semiconductor body. Thus, the current can be diffused more uniformly.

In the light-emitting device of the embodiment, the layered semiconductor body may have a corner when viewed in plan, and the n-side electrode may have a linear part facing the corner of the layered semiconductor body.

In this configuration, an interior angle of the angled part of the via and the n-side electrode is increased to reduce sharpness of the angled part. Thus, the via reaching the n-type layer and the n-side electrode can easily be formed.

In the light-emitting device of the embodiment, the layered semiconductor body may have a corner when viewed in plan, and the n-side electrode may have a branched part facing and extending toward the corner of the layered semiconductor body.

In this configuration, the n-side electrode can be brought closer to the layered semiconductor body by the branched part, and the current can be diffused to a vertex of the corner of the layered semiconductor body.

### EMBODIMENT

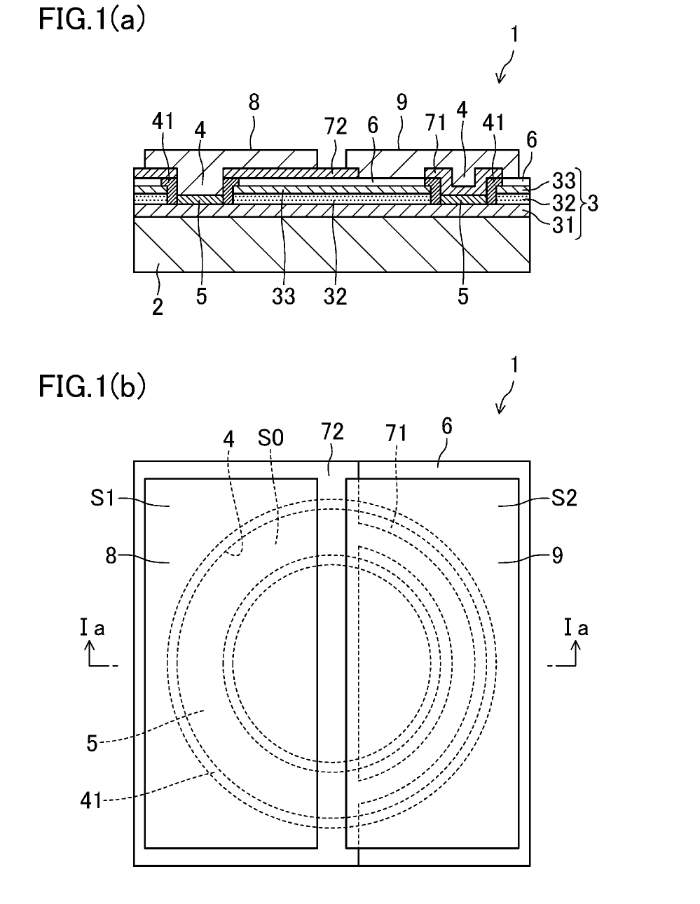

A light-emitting device of the embodiment will be described with reference to FIG. 1(a) and FIG. 1(b).

As shown in FIG. 1(a) and FIG. 1(b), the light-emitting device 1 of the embodiment is a flip-chip light-emitting diode (LED) device including a plurality of semiconductor layers stacked on a principal surface of a substrate 2, and a plurality of electrodes for feeding a current.

Specifically, the light-emitting device 1 of the embodiment includes, for example, the substrate 2, a layered semiconductor body 3 formed on the substrate 2 and provided with a via 4 having an annular shape when viewed in plan, an n-side electrode 5 formed on a bottom surface of the via 4, a p-side electrode 6 covering a top surface of the layered semiconductor body 3, an n-side insulating layer 71 formed on the n-side electrode 5, a p-side insulating layer 72 formed on the p-side electrode 6, an n-side pad electrode 8 connected to the n-side electrode 5, and a p-side pad electrode 9 connected to the p-side electrode 6.

The substrate 2 is transparent to light, and is square when viewed in plan. The substrate 2 may be made of n-type gallium nitride (GaN), n-type silicon carbide (SiC), sapphire (monocrystalline Al₂O₃), etc.

The layered semiconductor body 3 is provided by stacking an n-type layer 31, a light-emitting layer 32, and a p-type layer 33 in sequence on the substrate 2. The n-type layer 31 may be made of n-type aluminum gallium nitride (AlGaN), for example. Silicon (Si), germanium (Ge), etc. may suitably be used as n-type dopants added to the n-type layer 31.

The light-emitting layer 32 contains at least gallium (Ga) and nitrogen (N) as constituent elements, and contains a suitable amount of indium (In) as required, thereby emitting light having a desired light-emitting wavelength. The light-emitting layer 32 may be a monolayer structure, or may be a multiple quantum well (MQW) structure including at least a pair of an indium gallium nitride (InGaN) layer and a gallium nitride (GaN) layer. The light-emitting layer 32 with the multiple quantum well structure can further improve brightness of the emitted light. The p-type layer 33 may be made of p-type AlGaN.

The layered semiconductor body 3 can be formed on a principal surface of the substrate 2 by epitaxial growth, e.g., metal organic chemical vapor deposition (MOCVD). In place of the MOCVD method, hydride vapor phase epitaxy (HYPE), molecule beam epitaxy (MBE), etc. may be used.

The via 4 is a through hole penetrating the p-type layer 33 and the light-emitting layer 32 of the layered semiconductor body 3 to expose the n-type layer 31 below the light-emitting layer 32. For example, the via 4 may have a substantially annular shape when viewed in plan. In the light-emitting device 1 of the present embodiment, the via 4 has a closed annular shape, i.e., a circular shape. Thus, the n-type layer 31 exposed in a region S0 penetrated by the via 4 is circular when viewed in plan.

An insulating circumferential wall layer 41 is formed on an inner circumferential surface of the via 4 to bring the p-type layer 33 and the light-emitting layer 32 non-conductive with the n-side electrode 5. The insulating circumferential wall layer 41 may be made of silicon oxide (SiO₂), for example. The insulating circumferential wall layer 41 may be made of silicon nitride (SiN) or aluminum oxide (Al₂O₃) in place of silicon oxide.

The n-side electrode 5 is formed on the n-type layer 31 in a circular penetrated region S0 exposed in the via 4. The n-side electrode 5 may be a multilayer structure including an aluminum (Al) layer, a titanium (Ti) layer, and a gold (Au) layer stacked in sequence.

The p-side electrode 6 is formed on the p-type layer 33. The p-side electrode 6 is formed in a region except for the penetrated region S0 by the via 4. The p-side electrode 6 may be a multilayer structure including a nickel (Ni) layer, a silver (Ag) layer, and a titanium (Ti) layer stacked in sequence. The p-side electrode 6 including the Ag layer can function as a reflective layer.

The n-side insulating layer 71 and the p-side insulating layer 72 may be made of SiO₂, SiN, or Al₂O₃. The n-side insulating layer 71 is formed between the p-side pad electrode 9 and part of the n-side electrode 5 in the penetrated region S0 included in a p-side connection region S2. The p-side insulating layer 72 is formed between the n-side pad electrode 8 and part of the p-side electrode 6 included in an n-side connection region S1.

The n-side pad electrode 8 is provided in the n-side connection region S1 which is square when viewed in plan, and occupies almost half of the penetrated region S0. Thus, the n-side pad electrode 8 is formed on the n-side electrode 5 and the p-side insulating layer 72 in the n-side connection region S1, and is conductively connected to the n-side electrode 5. The n-side pad electrode 8 is connected to an n-side power supply (a cathode power supply) for the light-emitting device 1.

The p-side pad electrode 9 is formed in the p-side connection region S2 which is square when viewed in plan, and occupies almost the other half of the penetrated region S0. Thus, the p-side pad electrode 9 is formed on the p-side electrode 6 and the n-side insulating layer 71 in the p-side connection region S2, and is conductively connected to the p-side electrode 6. The p-side pad electrode 9 is connected to a p-side power supply (an anode power supply) for the light-emitting device 1.

### (Manufacturing Method)

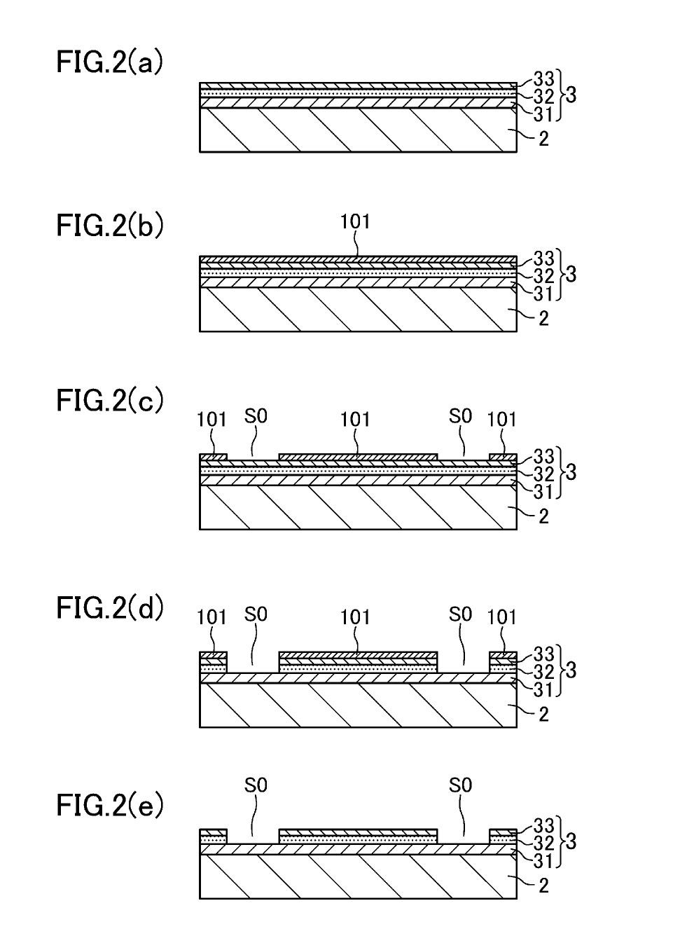

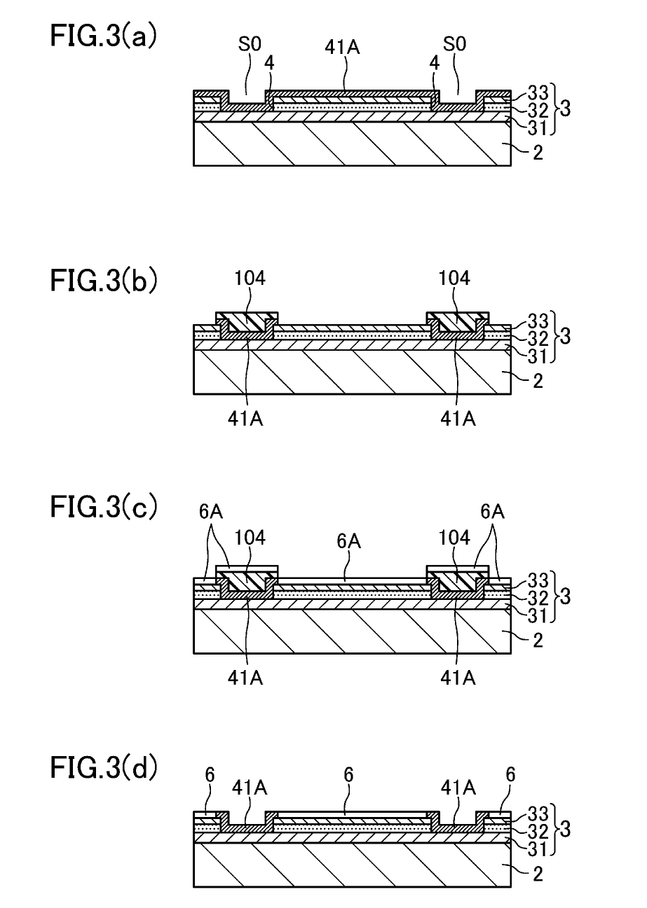

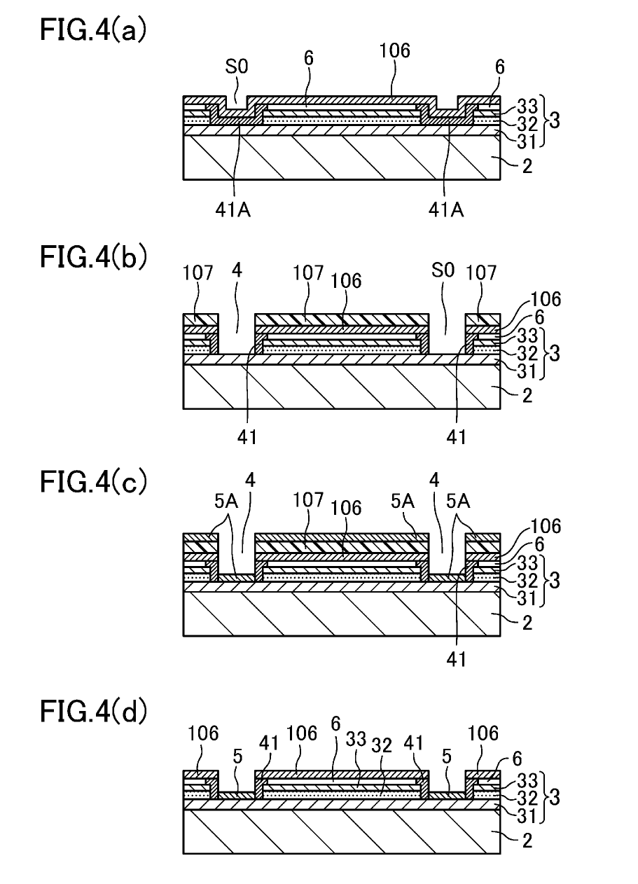

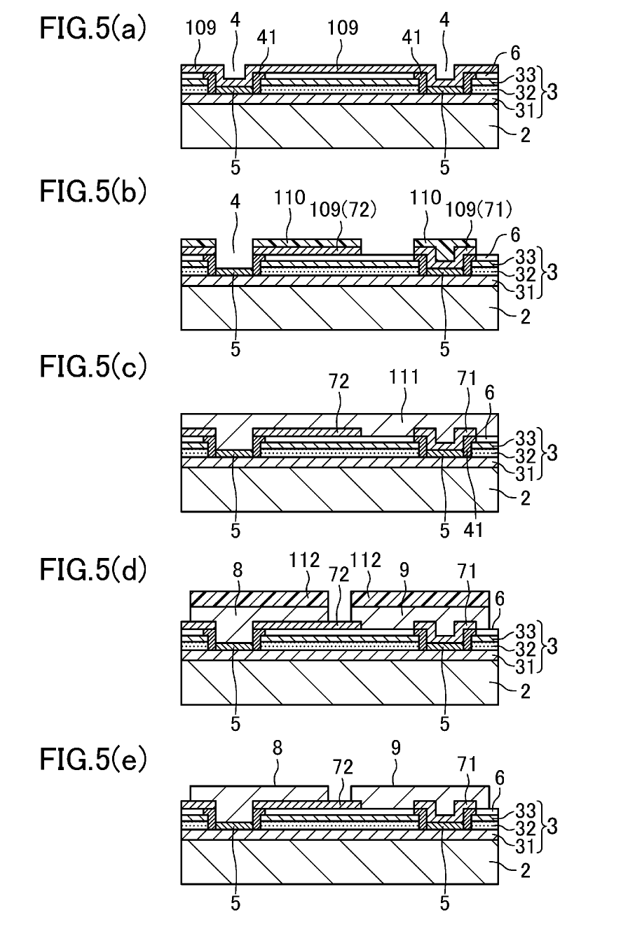

A method for manufacturing the light-emitting device of the present embodiment described above will be described with reference to FIG. 2(a)-FIG. 2(e), FIG. 3(a)-FIG. 3(d), FIG. 4(a)-FIG. 4(d) and FIG. 5(a)-FIG. 5(e). In an actual manufacturing method, the semiconductor layers are stacked on a substrate as a wafer which is divided into substrates 2 to fabricate a plurality of light-emitting devices 1 at one time. In the following description, a method for manufacturing a single light-emitting device will be shown in the drawings for convenience's sake.

First, as shown in FIG. 2(a), for example, an n-type layer 31 made of n-type AlGaN, a light-emitting layer 32 having a multiple quantum well structure including alternately stacked InGaN well layers and GaN barrier layers, and a p-type layer 33 made of p-type AlGaN are epitaxially grown on a principal surface of the substrate 2 by MOCVD, etc.

Then, as shown in FIG. 2(b), an insulating layer 101 as a mask layer made of SiO₂ is formed on the p-type layer 33.

Then, as shown in FIG. 2(c), an opening for forming a penetrated region S0 is formed in the insulating layer 101 by lithography and etching.

Then, as shown in FIG. 2(d), using as a mask the insulating layer 101 provided with the opening, the penetrated region S0 as a via is formed in the p-type layer 33 and the light-emitting layer 32 by reactive ion etching (RIE), for example.

Then, as shown in FIG. 2(e), the insulating layer 101 is removed.

Then, as shown in FIG. 3(a), an insulating layer 41A made of SiO₂, SiN, Al₂O₃, etc. is formed on the entire surface of the layered semiconductor body 3 including the penetrated region S0 by CVD, for example. Thus, the insulating layer 41A is formed on the p-type layer 33, part of the n-type layer 31 exposed in the penetrated region S0, and an inner circumferential wall of the via 4.

Then, a resist layer 104 covering the penetrated region S0 is formed on the insulating layer 41A by lithography. Then, as shown in FIG. 3(b), the insulating layer 41A is etched away using the resist layer 104 as a mask so that part of the insulating layer 41A is left in the penetrated region S0.

Then, as shown in FIG. 3(c), a Ni layer, a Ag layer, and a Ti layer are stacked in sequence on the resist layer 104 and the p-type layer 33 by sputtering, vacuum vapor deposition, etc. to form a metal layer 6A as a p-side electrode.

Then, as shown in FIG. 3(d), the resist layer 104 and the metal layer 6A on the resist layer 104 are removed by so-called lift-off to form a p-side electrode 6 made of the metal layer 6A on the p-type layer 33.

Then, as shown in FIG. 4(a), an insulating protective layer 106 made of SiO₂, for example, and protects the p-side electrode 6 is formed to cover the p-side electrode 6 and the insulating layer 41A covering the penetrated region S0.

Then, as shown in FIG. 4(b), a resist layer 107 provided with an opening over the penetrated region S0 is formed on the insulating protective layer 106 by lithography. Then, using the resist layer 107 as a mask, the insulating protective layer 106 and the insulating layer 41A are sequentially etched. Thus, the n-type layer 31 is exposed in the penetrated region S0, and an insulating circumferential wall layer 41 made of the insulating layer 41A is formed on an inner circumferential wall of the via 4.

Then, as shown in FIG. 4(c), an Al layer, a Ti layer, and a Au layer are stacked in sequence on the resist layer 107 and the n-type layer 31 exposed in the via 4 by sputtering, vacuum vapor deposition, etc. to form a metal layer 5A as an n-side electrode.

Then, as shown in FIG. 4(d), the resist layer 107 and the metal layer 5A on the resist layer 107 are removed by lift-off to form an n-side electrode 5 made of the metal layer 5A on the n-type layer 31 exposed in the via 4.

Then, as shown in FIG. 5(a), the insulating protective layer 106 is removed. Subsequently, an insulating layer 109 made of SiO₂, for example, is formed to cover the insulating circumferential wall layer 41, the inside of the via 4, and the p-side electrode 6.

Then, as shown in FIG. 5(b), a resist layer 110 is formed by lithography on the insulating layer 109. The resist layer 110 is provided with a first opening above the via 4 in the n-side connection region S1 connected to the n-side electrode 5 shown in FIG. 1(b), and a second opening above part of the p-side connection region S2 connected to the p-side electrode 6 shown in FIG. 1(b). Then, the insulating layer 109 is etched using the resist layer 110 as a mask. Thus, the n-side electrode 5 is exposed in the via 4 in the n-side connection region S1, and the p-side electrode 6 is exposed in the p-side connection region S2. In this step, the insulating layer 109 remaining in the n-side connection region S1 is the p-side insulating layer 72. The insulating layer 109 remaining in the penetrated region S0 in the p-side connection region S2 is the n-side insulating layer 71.

Then, as shown in FIG. 5(c), the resist layer 110 is removed, and a Ti layer and an Au layer are stacked in sequence to form a metal layer 111 as an n-side pad electrode and a p-side pad electrode by vacuum vapor deposition to cover the exposed n-side electrode 5 and p-side electrode 6, the n-side insulating layer 71, and the p-side insulating layer 72.

Then, as shown in FIG. 5(d), a resist layer 112 patterned to cover the n-side connection region S1 and the p-side connection region S2 shown in FIG. 1 is formed on the metal layer 111 by lithography. Then, the metal layer 111 is etched using the resist layer 112 as a mask. Thus, the metal layer 111 in the n-side connection region S1 is formed into an n-side pad electrode 8, and the metal layer 111 in p-side connection region S2 is formed into a p-side pad electrode 9.

Then, as shown in FIG. 5(e), the resist layer 112 is removed to obtain the light-emitting device 1 of the present embodiment.

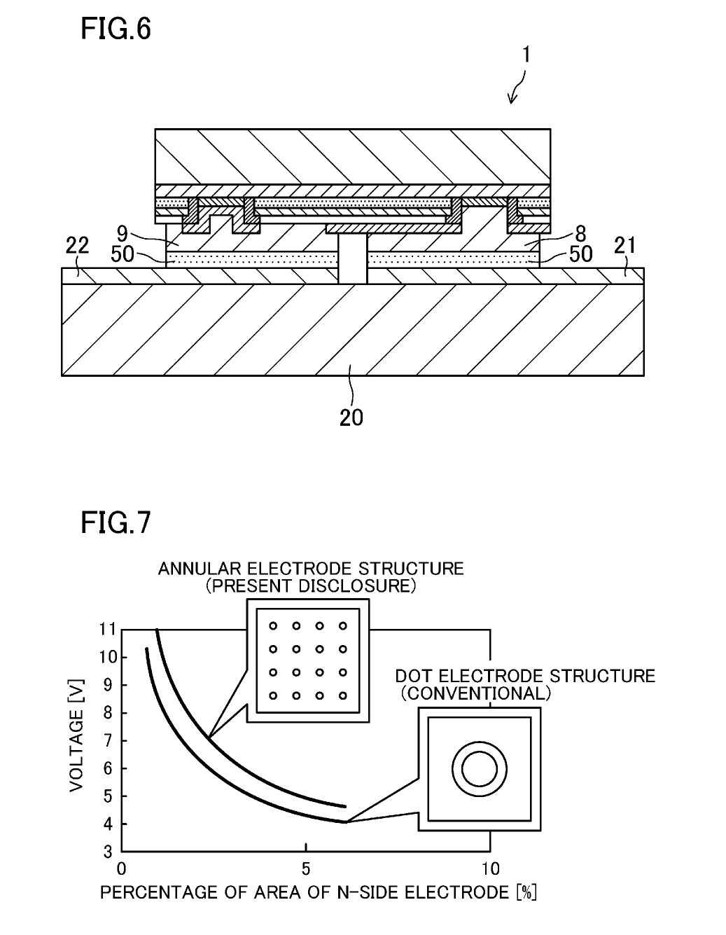

How the light-emitting device 1 of the present embodiment is mounted and used will be described below with reference to FIG. 6.

The light-emitting device 1 of the present embodiment can be mounted on a sub-mount device 20 for use. The sub-mount device 20 may be a protective element for a Zener diode, a varistor, a resistor, etc., or may simply be a mount base for flip-chip mounting the light-emitting device 1. On the sub-mount device 20, an n-side terminal 21 which is square when viewed in plan and is connected to the n-side pad electrode 8, and a p-side terminal 22 which is square when viewed in plan and is connected to the p-side pad electrode 9 are formed to be spaced from each other. The light-emitting device 1 can be mounted on the sub-mount device 20 with a conductive fixing member 50 such as solder, a bump, etc. interposed between the n-side and p-side terminals 21 and 22 and the light-emitting device 1.

By die-bonding the light-emitting device 1 onto the sub-mount device 20 in this way, power can be supplied to the light-emitting device 1 through wires (not shown) connected to the n-side terminal 21 and the p-side terminal 22.

Regarding the light-emitting device 1 of the present embodiment, a simulation is performed to see a relationship between a percentage of an area of the n-side electrode 5 with respect to the light-emitting layer 32 and a forward voltage.

In this simulation, the light-emitting device 1 is 0.8 mm×0.8 mm square in planar size (chip size), and a current of 1 A is applied.

The simulation is performed at the same time on a conventional light-emitting device described in Patent Document 1 as a comparative example. An electrode structure in the light-emitting device of Patent Document 1 is referred to as a dot electrode structure. The comparative light-emitting device has the same chip size as the light-emitting device of the present embodiment, i.e., 0.8 mm×0.8 mm, and the applied current is 1 A. For example, the annular n-side electrode 5 has an outer diameter of 190 μm, and an inner diameter of 120 μm when the percentage of the area of the n-side electrode is 3%. The dot electrode has a diameter of 37 μm when the percentage of the area of the n-side electrode is 3%.

FIG. 7 shows the results of the simulation. As apparent from the graph of FIG. 7, when the light-emitting device of the present embodiment and the comparative light-emitting device have the same percentage of the area of the n-side electrode, the light-emitting device of the present embodiment shows the forward voltage lower than that of the comparative light-emitting device. Thus, the light-emitting device of the present embodiment can reduce a drive voltage as compared with the comparative light-emitting device.

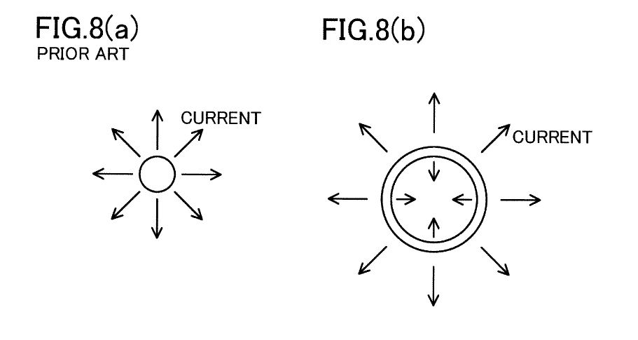

In the dot electrode structure including a plurality of dot-shaped n-side electrodes arranged in a dot array pattern, the current is diffused only in an outward direction from each of the dot-shaped n-side electrodes as shown in FIG. 8(a). In contrast, as shown in FIG. 8(b), the current is diffused not only in the outward direction, but also in an inward direction from the annular n-side electrode 5 of the present embodiment shown in FIG. 1. This can spread the current injected in the n-type layer 31 over a wide area of the n-type layer 31, and allows efficient and uniform light emission by the light-emitting layer 32. As a result, the light-emitting device 1 of the present embodiment can ensure a light-emitting region, can ensure favorable diffusion of the current, and can improve brightness of the emitted light.

### Alternative Examples

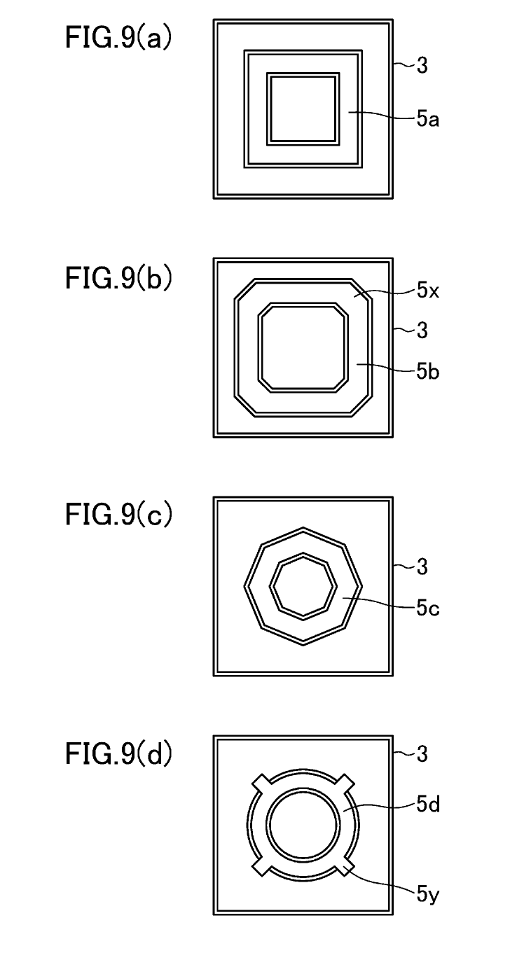

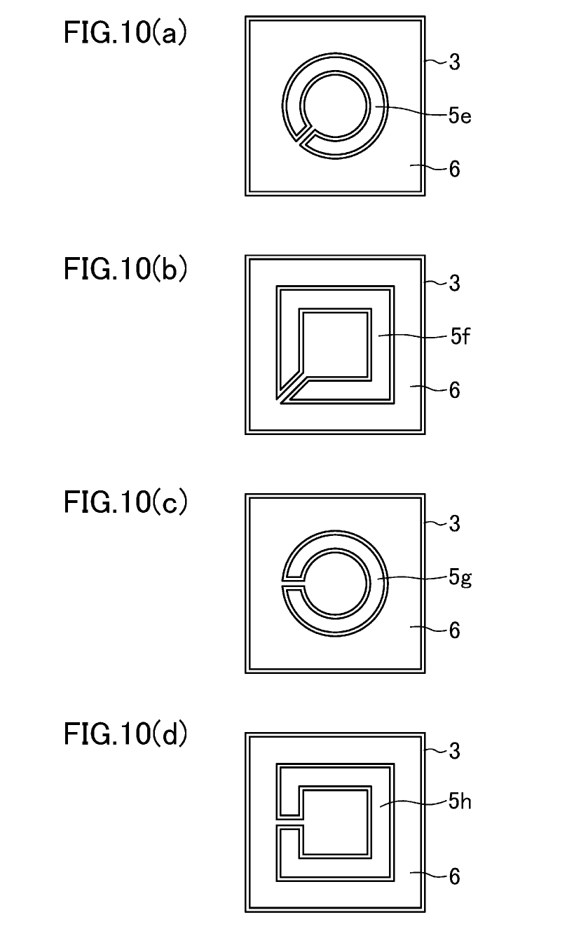

Various alternative examples of the planar shape of the n-side electrode of the light-emitting device will be described with reference to FIG. 9(a)-FIG. 9(d) and FIG. 10(a)-FIG. 10(d).

A light-emitting device of a first alternative example shown in FIG. 9(a) has an n-side electrode 5a which is square when viewed in plan. A light-emitting device of a second alternative example shown in FIG. 9(b) has an n-side electrode 5b which is subsequently square when viewed in plan. The n-side electrode 5b has linear parts 5x at corners thereof. A light-emitting device of a third alternative example shown in FIG. 9(c) has an n-side electrode 5c which is octagonal when viewed in plan.

The n-side electrodes 5a and 5c of the light-emitting devices of the first and third alternative examples shown in FIG. 9(a) and FIG. 9(c) have angled parts facing corners of the layered semiconductor body 3, respectively. In this configuration, the current can be diffused from the angled parts of the n-side electrode 5a, 5c to the corresponding corners of the layered semiconductor body 3, and the current can be diffused more uniformly.

In the light-emitting device of the second alternative example shown in FIG. 9(b), the n-side electrode 5b has the linear parts 5x facing the corners of the layered semiconductor body 3. Thus, an interior angle of each of the angled parts of the n-side electrode 5b is increased to reduce sharpness of the angled parts. This can facilitate the manufacture of the n-side electrode 5b.

The n-side electrode 5c of the third alternative example shown in FIG. 9(c) may also have the linear parts at the angled parts facing the corners of the layered semiconductor body 3. Instead of changing the planar shape of the n-side electrode 5c, the octagonal n-side electrode 5c may be arranged so that four of the external eight sides face the corners of the layered semiconductor body 3, respectively.

An annular n-side electrode 5d of a light-emitting device of a fourth alternative example shown in FIG. 9(d) has a plurality of branched parts 5y facing and extending toward the corners of the layered semiconductor body 3.

In the fourth alternative example, the n-side electrode 5d can be brought closer to the corners of the layered semiconductor body 3 by the branched parts 5y. Thus, the current can be diffused to vertexes of the corners of the layered semiconductor body 3.

The annular n-side electrode 5d of the fourth alternative example is provided with the branched parts 5y. Likewise, the n-side electrodes 5a-5c of the first to third alternative examples may also be provided with the branched parts 5y.

In the alternative examples described above, the four linear parts 5x or the four branched parts 5y are provided to face the four corners of the layered semiconductor body 3. However, the advantage of providing the linear parts or the branched parts can be obtained even if at least one linear part or at least one branched part is provided.

The n-side electrodes 5a-5d of the alternative examples shown in FIG. 9(a)-FIG. 9(d) have the closed annular shape when viewed in plan. N-side electrodes 5e-5h of light-emitting devices of fifth to eighth alternative examples shown in FIG. 10(a)-FIG. 10(d) have a partially opened annular shape when viewed in plan.

An n-side electrode 5e of the fifth alternative example shown in FIG. 10(a) is circular when viewed in plan, and is cut in a radial direction at a position facing one of the corners of the layered semiconductor body 3. An n-side electrode 5f of the sixth alternative example shown in FIG. 10(b) is square when viewed in plan, and is cut in a diagonal direction at a position facing one of the corners of the layered semiconductor body 3. An n-side electrode 5g of the seventh alternative example shown in FIG. 10(c) is circular when viewed in plan, and is cut in a radial direction at a position facing one of sides of the layered semiconductor body 3. An n-side electrode 5h of the eighth alternative example shown in FIG. 10(d) is square when viewed in plan, and is cut at one of its sides to face one of the sides of the layered semiconductor body 3.

When the annular n-side electrodes 5e-5h are partially opened as shown in FIG. 10(a)-FIG. 10(d), part of the p-side electrode 6 inside the n-side electrode 5e-5h and part of the p-side electrode 6 outside the n-side electrode 5e-5h are brought into conduction.

When the parts of the p-side electrode 6 inside and outside the n-side electrode 5 are in conduction, the p-side electrode 6 can be connected to the p-side pad electrode 9 through only a single connection point. This can increase layout flexibility of the n-side pad electrode 8 and the p-side pad electrode 9.

For example, the n-side electrode 5g of the seventh alternative example shown in FIG. 10(c) will be described as an example.

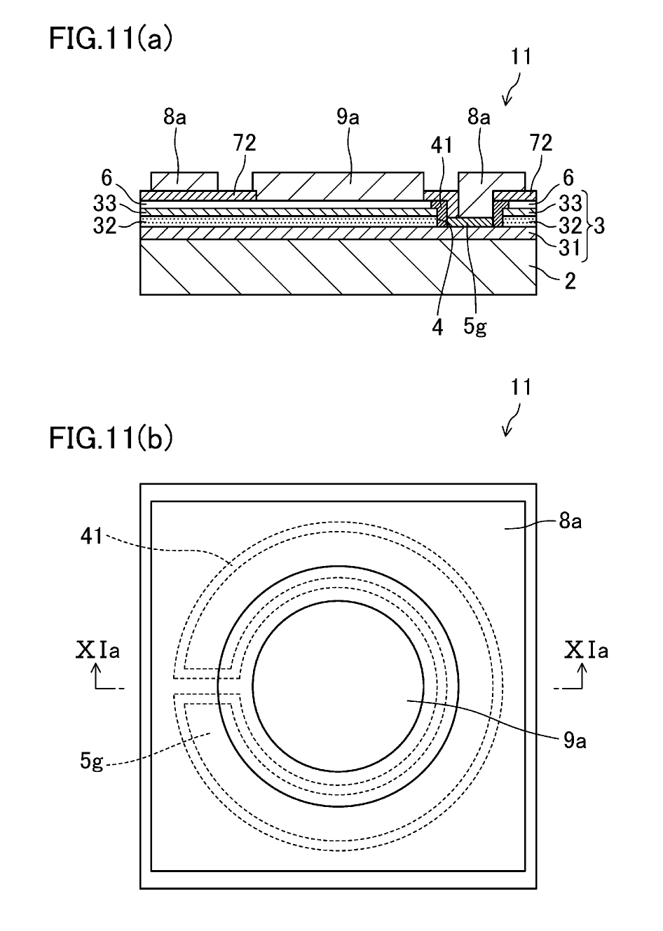

As shown in FIG. 11(a) and FIG. 11(b), the light-emitting device 11 is provided in which a region inside the n-side electrode 5g is the p-side pad electrode 9a, and a region outside the n-side electrode 5g including the n-side electrode 5g is the n-side pad electrode 8a.

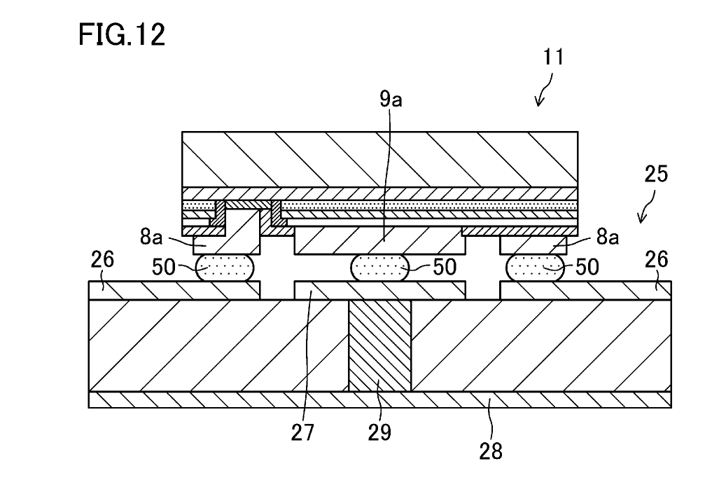

The light-emitting device 11 of the seventh alternative example can be mounted on a sub-mount device 25 shown in FIG. 12. The sub-mount device 25 includes a p-side terminal 27 formed on a center part of a top surface of the sub-mount device 25 to be connected to the p-side pad electrode 9a, and an n-side terminal 26 formed outside the p-side terminal 27 to be connected to the n-side pad electrode 8a. Further, the sub-mount device 25 is provided with a through hole 29 for conductively connecting the p-side pad electrode 9a and a bottom surface terminal 28. The light-emitting device 11 can be mounted on the sub-mount device 25 with a fixing member 50 such as solder, a bump, etc. interposed therebetween.

With the light-emitting device 11 mounted on the sub-mount device 25, power is supplied from the bottom surface terminal 28 to the p-side pad electrode 9a. Power is also supplied to the n-side pad electrode 8a through a wire (not shown) connected to the n-side terminal 26.

The light-emitting device of the embodiment and the alternative examples have been described above. However, the present disclosure is not limited to the embodiment and the alternative examples. For example, each of the n-side electrodes 5e-5h shown in FIGS. 10(a)-10(d) may be provided with a branched part facing and extending toward at least one of the corners of the layered semiconductor body 3. Further, each of the n-side electrodes 5e-5h shown in FIGS. 10(a)-10(d) may be provided with a linear part facing at least one of the corners of the layered semiconductor body 3.

### INDUSTRIAL APPLICABILITY

The present disclosure can ensure the light-emitting region, can ensure favorable diffusion of the injected current, and can improve brightness of the emitted light. Thus, the present disclosure is suitably applied to light-emitting devices etc. including an n-side electrode conductively connected to an n-type layer in a region penetrated by a via, and a p-type electrode conductively connected to a p-type layer.

### DESCRIPTION OF REFERENCE CHARACTERS

1, 11 Light-emitting device
2 Substrate
3 Layered semiconductor body
4 Via
5, 5a-5h N-side electrode
5A Metal layer
5x Linear part
6 P-side electrode
6A Metal layer
8, 8a N-side pad electrode
9, 9a P-side pad electrode
20, 25 Sub-mount device
21, 26 N-side terminal
22, 27 P-side terminal
28 Bottom surface terminal
29 Through hole
31 N-type layer
32 Light-emitting layer
33 P-type layer
41 Insulating circumferential wall layer
41A Insulating layer
50 Fixing member
71 N-side insulating layer
72 P-type insulating layer
101 Insulating layer
104 Resist layer
106 Insulating protective layer
107 Resist layer
109 Insulating layer
110 Resist layer
111 Metal layer
112 Resist layer
S0 Penetrated region
S1 N-side connection region
S2 P-side connection region

1. A light-emitting device, comprising:
a layered semiconductor body including an n-type layer, a light-emitting layer, and a p-type layer stacked in sequence;
an n-side electrode formed on part of the n-type layer exposed in a via formed in the layered semiconductor body to be non-conductive with the light-emitting layer and the p-type layer; and
a p-side electrode formed on the p-type layer, wherein
the n-side electrode has an annular shape on a principal surface of the n-type layer.

2. The light-emitting device of claim 1, further comprising:
an n-side pad electrode which is formed above the p-type layer of the layered semiconductor body, is electrically connected to the n-side electrode, and is provided in an n-side connection region connected to an n-side power supply;
a p-side pad electrode which is formed above the p-type layer of the layered semiconductor body, is electrically connected to the p-side electrode, and is provided in a p-side connection region connected to a p-side power supply;
a p-side insulating layer formed between the n-side pad electrode and part of the p-side electrode included in the n-side connection region; and
an n-side insulating layer formed between the p-side pad electrode and part of the n-side electrode included in the p-side connection region.

3. The light-emitting device of claim 1, wherein the n-side electrode has a closed annular shape.

4. The light-emitting device of claim 1, wherein the n-side electrode has a partially opened annular shape.

5. The light-emitting device of claim 1, wherein
the n-side electrode is circular or polygonal.

6. The light-emitting device of claim 1, wherein
the layered semiconductor body has a corner when viewed in plan, and
the n-side electrode has an angled part facing the corner of the layered semiconductor body.

7. The light-emitting device of claim 1, wherein
the layered semiconductor body has a corner when viewed in plan, and
the n-side electrode has a linear part facing the corner of the layered semiconductor body.

8. The light-emitting device of claim 1, wherein
the layered semiconductor body has a corner when viewed in plan, and
the n-side electrode has a branched part facing and extending toward the corner of the layered semiconductor body.

9. The light-emitting device of claim 2, wherein
the n-side electrode has a closed annular shape.

10. The light-emitting device of claim 2, wherein
the n-side electrode has a partially opened annular shape.
